(19) United States
(12) Patent Application Publication
(10) Pub. No.: US 2007/0141731 A1
(43) Pub. Date: Jun. 21, 2007

(54) Semiconductor memory with redundant replacement for elements posing future operability concern

(76) Inventors: Gerrit Jan Hemink, Yokohama (JP); Loc Tu, San Jose, CA (US); Jian Chen, San Jose, CA (US); Kiran Ponnuru, Sunnyvale, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/316,108

(22) Filed: Dec. 20, 2005

(51) Int. Cl. H01L 21/66; G01R 31/26

(52) U.S. Cl. 438/14

(57) ABSTRACT

Future operability predictor testing is incorporated into the fabrication of integrated circuits that utilize redundancy. Select reliability testing can be used to identify circuit elements such as memory cells that fail or become defective over time. Future operability tests and associated stress conditions are then developed for application during the fabrication process to identify memory cells that may pose a future operability concern before they actually fail. Memory cells that are determined to pose a future operability concern are replaced by redundant memory cells.

### BACKGROUND OF THE INVENTION

1. Field of the Invention

The present invention relates to technology for fabricating integrated circuits such as semiconductor memory devices.

2. Description of the Related Art

Semiconductor memory, including volatile memory such as dynamic or static random access memory and non-volatile memory such as flash memory, have become more popular for use in various electronic devices. For example, non-volatile semiconductor memory is used in cellular telephones, digital cameras, personal digital assistants, mobile computing devices, non-mobile computing devices and other devices. Electrically Erasable Programmable Read Only Memory (EEPROM), including flash EEPROM, and Electrically Programmable Read Only Memory (EPROM) are among the most popular non-volatile semiconductor memories.

As with most storage devices, semiconductor memory devices may have defective components or storage areas. For example, the individual storage elements or memory cells of a semiconductor memory array may be defective. Additionally, the peripheral circuitry for the memory array, including word lines, bit lines, decoders, etc., may be defective, rendering associated storage elements defective as well. It is inevitable in any commercially fabricated semiconductor memory device that some portion of the memory array will be defective.

Most defect management schemes rely on redundant memory cells to replace primary memory cells that are determined to be defective. During typical semiconductor memory fabrication processes such as that depicted in FIG. 1, wafer level testing 102 is conducted prior to packaging the memory chips to form memory devices. A wafer can include hundreds or thousands of memory chips, each of which will include a memory array and peripheral components such as the control and logic circuits for accessing the memory cells of the array. During wafer level testing 102, the functionality of the memory chips is tested so that defective components are not needlessly integrated into a packaged device. Wafer level testing is often conducted at raised and/or lowered temperatures (e.g., 85° C. and/or −30° C.) to ensure functionality at extreme conditions and to ensure functionality after stressing the circuits. Memory cells that fail functionality testing can be replaced by redundant memory cells. Depending on the type of memory being manufactured, different redundancy schemes can be employed. For example, individual memory cells can be replaced, entire columns or bit lines of memory cells can be replaced, or entire blocks of memory cells can be replaced.

After wafer level testing 102, the wafer is divided into individual memory chips and one or more of the memory chips are packaged 104 to form a memory device. Packaged memory devices are then subjected to a burn-in process 106 to stress the memory arrays and peripheral circuitry of the chips. Burn-in is typically conducted under even higher temperatures (e.g., 125° C.) than wafer level testing. High voltages are applied at various portions of each chip to stress and identify weaker elements. The stress conditions of the burn-in process are designed to cause failure of weaker devices which can later be detected during package level testing 108. In some manufacturing processes, burn-in is not performed.

Package level testing usually consists of various functionality tests to determine which cells are defective subsequent to burn-in. In recent years, techniques such as anti-fuses have been incorporated into fabrication processes so that memory cells found to be defective subsequent to burn-in can be replaced by redundant memory. Various performance level tests can also be conducted during package level testing to identify stronger or weaker memory devices.

As semiconductor memory capacity expands, so too does the number of defective memory cells and thus, the required redundancy capacity. Inherently, it is desirable to minimize the amount of memory devoted to redundancy so that the amount of memory made available for user data is maximized. Accordingly, it is desirable to efficiently use redundant memory elements and to avoid allocating too much chip area to redundancy. While current fabrication processes have evolved to provide some solutions for defective memory, inefficiencies remain.

Thus, there is a need for an improved and more efficient fabrication process and associated semiconductor memory.

### SUMMARY OF THE INVENTION

Future operability predictor testing is incorporated into the fabrication of integrated circuits that utilize redundancy. Select reliability testing can be used to identify circuit elements such as memory cells that fail or become defective over time. Future operability tests and associated stress conditions are then developed for application during the fabrication process to identify memory cells that may pose a future operability concern before they actually fail. Memory cells that are determined to pose a future operability concern are replaced by redundant memory cells.

In one embodiment, a method of manufacturing integrated circuits is provided that includes testing a plurality of circuit devices by applying at least one functionality test and at least one future operability test. The circuit devices include a plurality of primary storage elements and a plurality of redundant storage elements. After testing the devices, the method includes replacing primary storage elements that pass the at least one functionality test but fail the at least one future operability predictor test with redundant storage elements of the circuit devices. Testing and replacing the primary storage elements can be performed during wafer level testing and/or package level testing.

In one embodiment, a method of manufacturing integrated circuits is provided that includes testing at least one wafer including a plurality of memory chips. Each of the memory chips includes primary storage elements and redundant storage elements. Based on the testing, primary storage elements that fail functionality testing are replaced with redundant storage elements. After testing the at least one wafer, a packaged memory device is created from one or more of the memory chips. The packaged memory device is stressed and tested by applying at least one functionality test and at least one future operability predictor test. After applying the tests, the method replaces primary storage elements of the packaged memory device that pass the at least one functionality test but fail the at least one future operability predictor test with redundant storage elements of the packaged memory device.

### BRIEF DESCRIPTION OF THE DRAWINGS

FIG. 1 is a flowchart of a conventional semiconductor memory fabrication process.

FIG. 2 is a top view of a NAND string.

FIG. 3 is an equivalent circuit diagram of the NAND string depicted in FIG. 2.

FIG. 4 is a cross-sectional view of the NAND string depicted in FIG. 2.

FIG. 5 is a block diagram of an array of NAND flash memory cells.

FIG. 6 is a block diagram of a non-volatile memory system including an array of memory cells.

FIG. 7 is a flowchart describing one embodiment of fabricating semiconductor memory and formulating future operability tests.

FIG. 8 is a flowchart describing one embodiment of fabricating semiconductor memory using future operability testing and redundant cell replacement.

FIG. 9 is a flowchart describing one embodiment of fabricating semiconductor memory using future operability testing and redundant cell replacement.

FIG. 10 is a block diagram depicting one embodiment of a sense block of FIG. 6.

FIG. 11 is a flow chart describing one embodiment of a process for programming non-volatile memory.

FIG. 12 is an exemplary wave form applied to the control gates of non-volatile memory cells.

FIG. 13 depicts an exemplary set of threshold voltage distributions.

FIG. 14 depicts an exemplary set of threshold voltage distributions.

FIG. 15 is a flow chart describing one embodiment of a process for reading non-volatile memory.

FIG. 16 is a flowchart describing one embodiment of a process for performing a read operation for non-volatile memory.

### DETAILED DESCRIPTION

One example of an integrated circuit that can be fabricated in accordance with embodiments is a non-volatile memory system that uses the NAND flash memory structure, which includes arranging multiple transistors in series between two select gates. While NAND structures are described herein for exemplary purposes, it will be appreciated that the discussion is not so limited and has application to numerous types of integrated circuits. For example, the disclosure has equal applicability to NOR type flash memory and volatile memories such as DRAM and SRAM.

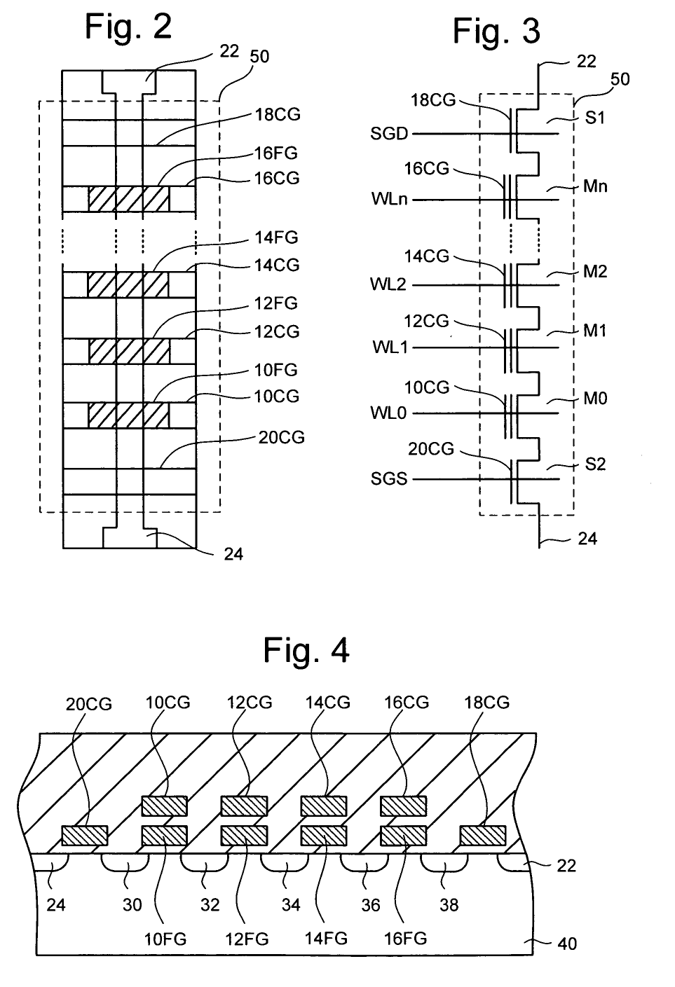

In FIG. 2, the transistors in series and the select gates are referred to as a NAND string. FIG. 2 is a top view showing an exemplary NAND string 50. FIG. 3 is an equivalent circuit thereof. The NAND string depicted in FIGS. 2 and 3 includes transistors, M0, M1, M2, and Mn, in series and sandwiched between a first select gate S1 and a second select gate S2. In one embodiment, transistors M0, M1, M2, and Mn each form an individual memory cell of the NAND string. In other embodiments, the memory cells of a NAND string may include multiple transistors or may be different than that depicted in FIGS. 2 and 3. The memory cell Mn is labeled as such to indicate that a NAND string can include any number (n) memory cells, be it less than or greater than four as depicted (e.g., 2, 8, 16, 32, etc.). The discussion herein is not limited to any particular number of memory cells in a NAND string. Select gate SI connects the NAND string to drain terminal 22 which is in turn connected to a bit line (not shown). Select gate S2 connects the NAND string to source terminal 24 which is in turn connected to a source line (not shown). Select gate S1 is controlled by applying the appropriate voltages to control gate 18CG via select line SGD and select gate S2 is controlled by applying the appropriate voltages to control gate 20CG via select line SGS. Each of the transistors M0, M1, M2, and Mn has a control gate and a floating gate. Transistor M0 includes control gate 10CG and floating gate 10FG. Transistor M1 includes control gate 12CG and floating gate 12FG. Transistor M2 includes control gate 14CG and floating gate 14FG. Transistor Mn includes control gate 16CG and floating gate 16FG. Control gate 10CG is connected to word line WLO, control gate 12CG is connected to word line WL1, control gate 14CG is connected to word line WL2, and control gate 16CG is connected to word line WLn.

FIG. 4 provides a cross-sectional view of the NAND string described above, wherein it is assumed that there are four memory cells in the NAND string. Again, the discussion herein is not limited to any particular number of memory cells in a NAND string. As depicted in FIG. 4, the transistors of the NAND string are formed in p-well region 40. Each transistor includes a stacked gate structure that consists of a control gate (10CG, 12CG, 14CG and 16CG) and a floating gate (10FG, 12FG, 14FG and 16FG). The floating gates are formed on the surface of the p-well on top of an oxide or other dielectric film. The control gate is above the floating gate, with an inter-polysilicon dielectric layer separating the control gate and floating gate. The control gates of the memory cells (M0, M1, M2 and Mn) form the word lines. N+ doped layers 30, 32, 34, 36 and 38 are shared between neighboring cells, whereby the cells are connected to one another in series to form a NAND string. These N+ doped layers form the source and drain of each of the elements of the string. For example, N+ doped layer 30 serves as the drain of transistor S2 and the source for transistor M0, N+ doped layer 32 serves as the drain for transistor M0 and the source for transistor M1, N+ doped layer 34 serves as the drain for transistor M1 and the source for transistor M2, N+ doped layer 36 serves as the drain for transistor M2 and the source for transistor Mn, and N+ doped layer 38 serves as the drain for transistor Mn and the source for transistor S1. N+ doped layer 22 forms the drain terminal and connects to a common bit line for multiple NAND strings, while N+ doped layer 24 forms the source terminal and connects to a common source line for multiple NAND strings.

Each memory cell can store data represented in analog or digital form. When storing one bit of digital data, the range of possible threshold voltages of the memory cell is divided into two ranges which represent distinct memory states. The memory states are assigned logical data “1” and “0.” At least one current breakpoint level is generally established so as to partition the conduction window of the memory cell into the two ranges. When the cell is read by applying predetermined, fixed voltages, its source/drain conduction current is resolved into one of the memory states by comparing it with the breakpoint level (or reference current). If the current read is higher than that of the breakpoint level, the cell is determined to be “on” and in one logical state. If the current is less than the breakpoint level, the cell is determined to be “off” and in the other logical state. In one example of a NAND-type flash memory, the voltage threshold is negative after the memory cell is erased, and defined as logic “1.” The threshold voltage is positive after a program operation, and defined as logic “0.” When the threshold voltage is negative and a read is attempted by applying 0 volts to the control gate, the memory cell will turn on to indicate logic one is being stored. When the threshold voltage is positive and a read operation is attempted by applying 0 volts to the control gate, the memory cell will not turn on to indicate that logic zero is being stored.

A memory cell can also store multiple bits of digital data by utilizing more than two ranges of threshold voltages to represent distinct memory states. The threshold voltage window can be divided into the number of desired memory states and multiple breakpoint levels used to resolve the individual states. For example, if four states are used, there will be four threshold voltage ranges representing four distinct memory states which are assigned the data values “11,” “10,” “01,” and “00.” In one example of a NAND-type memory, the threshold voltage after an erase operation is negative and defined as “11.” Positive threshold voltages are used for the states of “10,” “01,” and “00.” In some implementations, the data values (e.g., logical states) are assigned to the threshold ranges using a Gray code assignment so that if the threshold voltage of a floating gate erroneously shifts to its neighboring physical state, only one bit will be affected. The specific relationship between the data programmed into the memory cell and the threshold voltage ranges of the cell depends upon the data encoding scheme adopted for the memory cells. For example, U.S. Pat. No. 6,222,762 and U.S. patent application Ser. No. 10/461,244, “Tracking Cells For A Memory System,” filed on Jun. 13, 2003, both of which are incorporated herein by reference in their entirety, describe various data encoding schemes for multi-state flash memory cells.

Relevant examples of NAND-type flash memories and their operation are provided in the following U.S. patents/patent applications, all of which are incorporated herein by reference in their entirety: U.S. Pat. No. 5,570,315; U.S. Pat. No. 5,774,397; U.S. Pat. No. 6,046,935; U.S. Pat. No. 5,386,422; U.S. Pat. No. 6,456,528; and U.S. patent application Ser. No. 09/893,277 (Publication No. US2003/0002348). Other types of non-volatile memory in addition to NAND flash memory can also be used in accordance with embodiments.

Another type of memory cell useful in flash EEPROM systems utilizes a non-conductive dielectric material in place of a conductive floating gate to store charge in a non-volatile manner. Such a cell is described in an article by Chan et al., “A True Single-Transistor Oxide-Nitride-Oxide EEPROM Device,” IEEE Electron Device Letters, Vol. EDL-8, No. 3, March 1987, pp. 93-95. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. See also Nozaki et al., “A 1-Mb EEPROM with MONOS Memory Cell for Semiconductor Disk Application,” IEEE Journal of Solid-State Circuits, Vol. 26, No. 4, April 1991, pp. 497-501, which describes a similar cell in a split-gate configuration where a doped polysilicon gate extends over a portion of the memory cell channel to form a separate select transistor. The foregoing two articles are incorporated herein by reference in their entirety. The programming techniques mentioned in section 1.2 of “Nonvolatile Semiconductor Memory Technology,” edited by William D. Brown and Joe E. Brewer, IEEE Press, 1998, incorporated herein by reference, are also described in that section to be applicable to dielectric charge-trapping devices. The memory cells described in this paragraph can also be used with the present invention.

Another approach to storing two bits in each cell has been described by Eitan et al., “NROM: A Novel Localized Trapping, 2-Bit Nonvolatile Memory Cell,” IEEE Electron Device Letters, vol. 21, no. 11, November 2000, pp. 543-545. An ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. The memory cells described in this paragraph can also be used with the present invention.

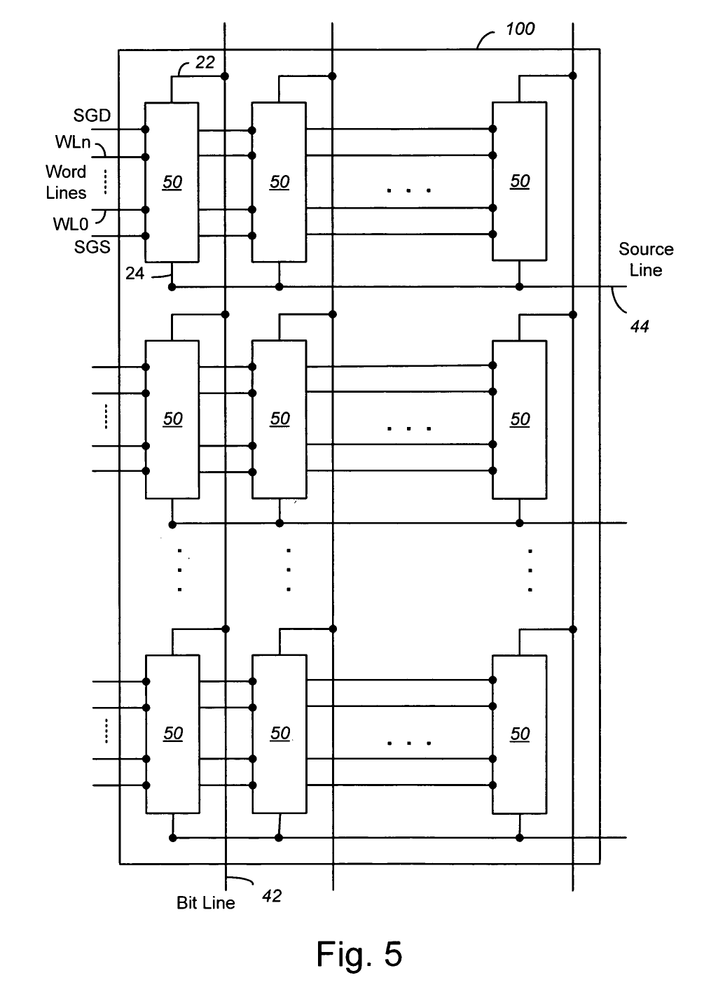

FIG. 5 illustrates an example of an array 100 of NAND strings 50, such as those shown in FIGS. 2-4. Along each column, a bit line 42 is coupled to the drain terminal, e.g. 22, of the drain select gate for the NAND string 50. Along each row of NAND strings, a source line 44 may connect all the source terminals, e.g. 24, of the source select gates of the NAND strings. An example of a NAND architecture array and its operation as part of a memory system is found in U.S. Pat. Nos. 5,570,315; 5,774,397; and 6,046,935.

The array 100 of memory cells is divided into a large number of blocks of memory cells. As is common for flash EEPROM systems, the block is the unit of erase. That is, each block contains the minimum number of memory cells that are erased together. Each block is typically divided into a number of pages. A page is a unit of programming or reading, although more than one page may be programmed or read in a single operation. In one embodiment, the individual pages may be divided into segments and the segments may contain the fewest number of cells that are written at one time as a basic programming operation. One or more pages of data are typically stored in one row of memory cells. A page can store one or more sectors of data, the size of which is generally defined by a host system. A sector includes user data and overhead data. Overhead data typically includes an Error Correction Code (ECC) that has been calculated from the user data of the sector. A portion of the controller (described below) calculates the ECC when data is being programmed into the array, and also checks it when data is being read from the array. Alternatively, the ECCs and/or other overhead data are stored in different pages, or even different blocks, than the user data to which they pertain.

A sector of user data is typically 512 bytes, corresponding to the size of a sector in magnetic disk drives. Overhead data is typically an additional 16-20 bytes. A large number of pages form a block, anywhere from 8 pages, for example, up to 32, 64 or more pages. In some embodiments, a row of NAND strings comprises a block.

Memory cells are erased in one embodiment by raising the p-well to an erase voltage (e.g., 20 volts) for a sufficient period of time and grounding the word lines of a selected block while the source and bit lines are floating. Due to capacitive coupling, the unselected word lines, bit lines, select lines, and c-source are also raised to a significant fraction of the erase voltage. A strong electric field is thus applied to the tunnel oxide layers of selected memory cells and the data of the selected memory cells are erased as electrons of the floating gates are emitted to the substrate side. As electrons are transferred from the floating gate to the p-well region, the threshold voltage of a selected cell is lowered. Erasing can be performed on the entire memory array, separate blocks, or another unit of cells.

Erase operations can lead to differing erase rates amongst memory cells in a NAND string and different threshold voltages after application of one or more erase voltage pulses. To overcome this effect, a technique generally referred to as soft programming has been used to adjust the threshold voltages of one or more memory cells after erasure. Soft programming includes applying a relatively low program voltage—lower than used for actual programming—to one or more memory cells. Soft programming typically includes applying a program voltage as a series of pulses that are increased by a step size in between each application of the program voltage pulses. Soft programming raises the memory cells' threshold voltages in order to narrow and/or raise the threshold voltage distribution of the population of erased memory cells to around a soft programming verify level (e.g., −0.8V to −1V).

When programming a flash memory cell, a program voltage is applied to the control gate and the bit line is grounded. Electrons from the p-well are injected into the floating gate. When electrons accumulate in the floating gate, the floating gate becomes negatively charged and the threshold voltage of the cell is raised. More details regarding erasing, programming, and reading memory cells are provided hereinafter.

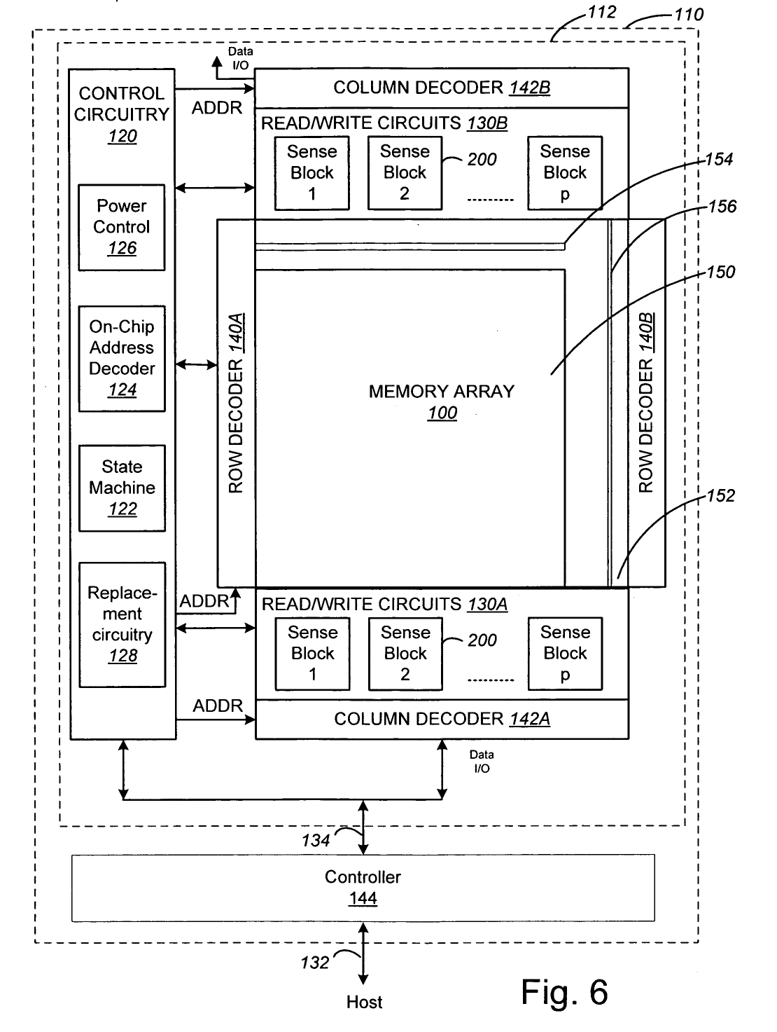

FIG. 6 illustrates a memory device 110 in accordance with one embodiment having read/write circuits for reading and programming a page of memory cells in parallel. Memory device 110 may include one or more memory die or chips 112. Memory die 112 includes a two or three-dimensional array of memory cells 100, control circuitry 120, and read/write circuits 130A and 130B. Access to the memory array 100 by the various peripheral circuits can be implemented in a symmetric fashion, on opposite sides of the array, so that the densities of access lines and circuitry on each side are reduced by half. In other embodiments, asymmetrical implementations are used. The read/write circuits 130A and 130B include multiple sense blocks 200 and allow a page of memory cells to be read or programmed in parallel. The memory array 100 is addressable by word lines via row decoders 140A and 140B and by bit lines via column decoders 142A and 142B. Typically a controller 144 is included in the same memory device 110 (e.g., a removable storage card) as the one or more memory die 112. Commands and Data are transferred between the host and controller 144 via lines 132 and between the controller and the one or more memory die 112 via lines 134.

The control circuitry 120 cooperates with the read/write circuits 130A and 130B to perform memory operations on the memory array 100. The control circuitry 120 includes a state machine 122, an on-chip address decoder 124 and a power control module 126. The state machine 122 provides chip-level control of memory operations. The on-chip address decoder 124 provides an address interface between that used by the host or a memory controller to the hardware address used by the decoders 140A, 140B, 130A, and 130B. The power control module 126 controls the power and voltages supplied to the word lines and bit lines during memory operations.

Memory array 100 is divided into a user data section 150 containing primary memory cells and a redundancy section 152 containing redundant memory cells. As typically provided in NAND memory structures, redundant memory cells 152 are partitioned into redundant blocks 154 comprising one or more word lines of memory cells, and redundant columns or bit lines 156. If a memory cell is defective, a redundant bit line or block can replace the bit line or block containing the defective memory cell. Other redundancy partitions can be used in other embodiments. For example, redundant memory cells or redundant word lines can be used to replace defective memory cells.

Replacement circuitry 128 is provided within control circuitry 120 to effectuate the replacement using redundant memory cells. Numerous types of redundant memory cell replacement circuitry can be used in accordance with embodiments. For example, replacement circuitry 128 can include fuses that are selectively conditioned (e.g., blown) during fabrication to store replacement data for addressing the redundant memory cells when a defective memory cell address is received. State machine 122 can read the data from the replacement circuitry at start-up or in response to access requests to effect the correct replacement when one or more defective memory cells lie within a requested address range. Replacement circuitry 128 essentially changes the addresses for the defective memory cells. When an address signal references an address range containing a defective memory cell, state machine 122 can use the information in replacement circuitry 128 to internally address the appropriate redundant memory cell, row, column, or block. The fuses will be configured in accordance with the desired replacement scheme; for example, to provide row and column or block and column replacement. In one embodiment, the redundancy replacement data for the replacement circuitry 128 is provided directly from memory array 100 and can be loaded in replacement circuitry and/or state machine 122 during use. State machine 122 can access the replacement circuitry to correctly address the memory during operation.

Numerous techniques for programming replacement circuitry 128 can be used in accordance with embodiments. Common techniques include laser blown or annealed fuses, electrically blown fuses, and electrically programmable fuses (so called e-fuses or anti-fuses). Laser blown fuses use a laser beam to cut traces (e.g., polysilicon or metal) and thereby interrupt current paths to create electrical opens or shorts. Electrically blown fuses operation on the same concept but use high voltages or currents to blow the fuses. Laser and electrically blown fuses typically require direct access to the memory chip and consequently can only be used during wafer level testing (prior to packaging).

Electrically programmable fuses utilize programmable nonvolatile memory elements to control the replacement circuitry. Electrically programmable fuses can be accessed and programmed both before after device packaging. In one embodiment that uses programmable fuses, the redundancy replacement data for the replacement circuitry 128 is provided directly within memory array 100 and can be loaded in replacement circuitry 128.

Conventional fabrication techniques have been limited in their use of redundant memory cell replacement. For example, redundant memory cells have only been used to replace primary memory cells that are determined not to be functional. These techniques present a less than optimal solution with a lack of efficiency. After replacing non-functional memory cells, there may be leftover redundant memory cells that are not used. In accordance with one embodiment, redundant memory cells are used to replace select primary memory cells that pass functionality testing. Future operability predictor tests can be applied during the fabrication process. Cells that pose a future operability concern can be identified on the basis of this testing and replaced with redundant memory cells.

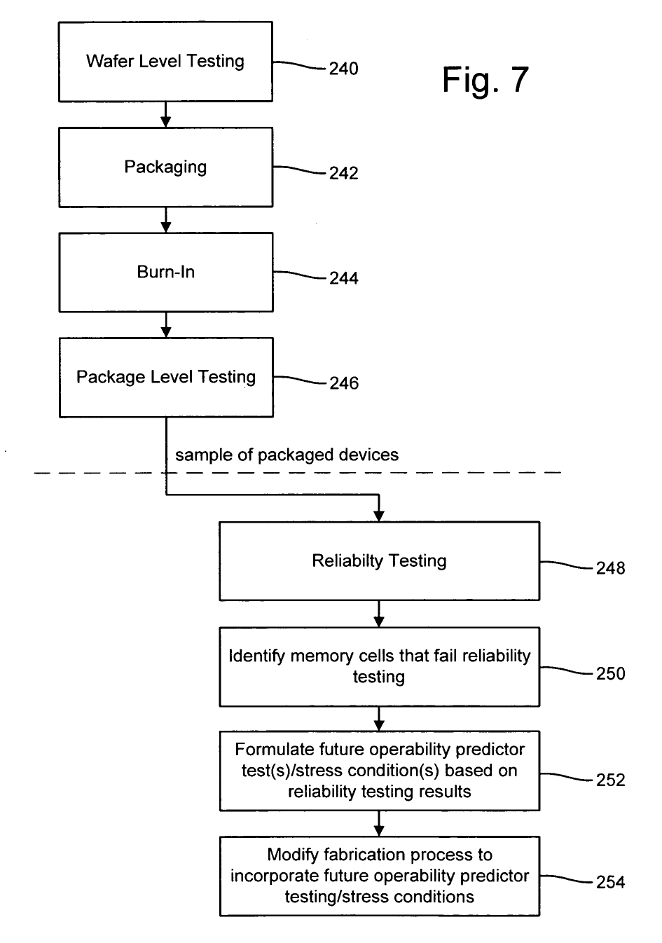

FIG. 7 is a flowchart in accordance with one embodiment for formulating future operability predictor tests based on a reliability analysis performed on select semiconductor memory devices of a group of devices being fabricated. As described earlier, conventional fabrication processes begin with a wafer of many memory chips or memory die (array and peripheral circuitry) which undergoes wafer level testing 240 and packaging 242 to form the individual semiconductor memory devices. The devices then undergo an optional burn-in 244 and package level testing 246. Every device manufactured undergoes the process outlined in boxes 240-246 to replace defective memory cells (e.g., during wafer level testing 240) when possible and to verify the device's functionality prior to being shipped. Variations to steps 240-246 can be used. For example, burn-in 244 can be performed at the wafer level before packaging. Additionally, stress conditions can be implemented during wafer level testing 240 and/or package level testing 246 in addition to or as a substitute for burn-in 244 processes.

To further improve the fabrication process, select devices are usually chosen to undergo additional reliability testing. Reliability testing can be performed on select devices of a production line before providing the fabricated devices to consumers, etc. Additionally, devices can be sampled during ongoing fabrication runs for reliability testing to further refine and improve the fabrication process.

In accordance with one embodiment, reliability testing is performed at step 248 on a sample of one or more packaged memory devices. Reliability testing is a type of functionality testing performed to determine whether devices remain functional over a period of time and use. Various reliability tests can be performed and different memory implementations will require different reliability tests. One type of reliability testing that can be performed at step 248 includes testing whether a memory device remains operable after repeated write/erase cycling. Numerous write and erase cycles for the memory device can be performed by repeatedly programming and erasing the memory cells of the device. This can simulate a long period of use of the device and the stresses that a memory device will experience over time. After repeatedly writing and erasing the memory cells, defective memory cells are identified by determining whether the cells are still capable of storing a charge (writing), having the level of charge stored in the device determined (reading), and having the charge removed from the floating gate or other charge storage region (erasing). Memory cells that do not program, read, or erase properly after the write/erase cycling tests are identified as defective and having failed the reliability test(s) at step 250. The failure of memory cells to withstand write/erase cycling is indicative of a reliability concern with the device. The reliability concern may be due to the cell itself, the bit lines, word lines, etc. of the memory array, or various other portions of the peripheral circuitry.

Another type of reliability testing 248 includes testing the data retention capability of the memory device. Data retention testing determines whether the memory cells of the device are capable of storing data for a minimum amount of time. Stresses such as high heat environments, etc. can be used to simulate a period of use of the device. After writing data to the device, stressing, and/or waiting for some period of time, the memory cells are read to determine whether they were able to retain the stored charge, and consequently, the data written to them. Memory cells that are unable to retain data written to them are identified as defective and having failed the reliability test(s) at step 250. An inability to retain data stored in a memory cell is indicative of a reliability concern with the device.

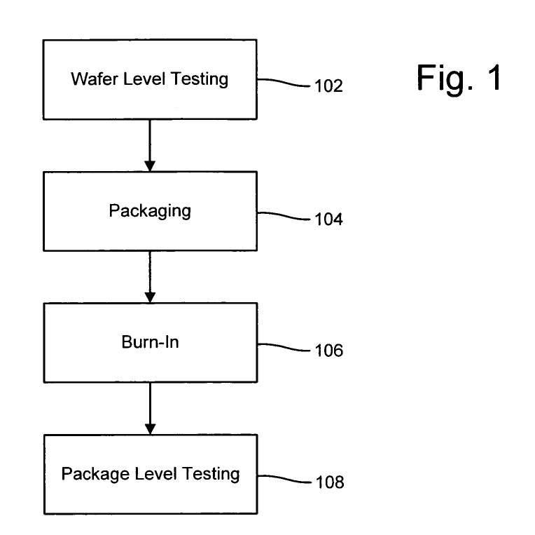

As previously described, reliability tests are not performed for each device fabricated during the manufacturing process. Therefore, it is desirable to be able to identify memory cells that pose a reliability concern, without having to subject every memory device of a production line to reliability testing. Accordingly, after identifying memory cells that fail reliability testing, future operability predictor test(s) and/or stress condition(s) are formulated at step 252. These tests and stress conditions can be inserted into the manufacturing process (e.g., FIG. 1) at step 254 to identify memory cells that may pose a future operability concern, even though they are determined to be functional at the time of testing.

The development of future operability predictor tests is a dynamic process that depends upon the type of reliability issues revealed during the reliability testing process. A key component of any future operability predictor test is to be able to identify memory cells during the fabrication process that may pose some future operability or reliability concern, but that are functional at the time of testing. Accordingly, when a reliability issue is identified, tests and stress conditions are developed so that memory cells that may suffer from the reliability issue can be identified during the fabrication process, without undergoing actual reliability testing to cause an actual detectable failure of the memory cells.

Consider the following example of a bad bit line within a memory device. A bit line may be accidentally shorted (e.g., to a neighboring bit line or neighboring drain side select gate) as the result of a defect during the fabrication process. A typical functionality test performed during wafer level or package level testing can detect the defect so that the column of memory cells associated with the shorted bit line can be replaced by a redundant column of memory cells. Now consider a bit line that isn't actually shorted, but that is fabricated perilously close to another bit line of the memory structure, for example. During wafer level testing 240 and package level testing 246, the defect is not detected because the memory device is presently functional. During reliability testing, however, the column of cells fails and it is determined that the bit line of the column is shorted. Because the problem only reveals itself as a result of the additional stresses applied during reliability testing, a future operability predictor test and/or stress condition is developed at step 252 to be inserted into the fabrication process at step 254.

It may be determined that the reliability issue manifests itself by way of current leakage from the affected bit line before the bit line is actually shorted. A future operability test could be developed to detect current leakage in the memory array's bit lines. Additionally, a burn-in condition could be developed to stress the bit lines, for example, by applying a high voltage to each bit line or by applying a high voltage to each select gate while applying a low voltage to the bit lines. The stress conditions applied to the bit lines may induce current leakage in weaker bit lines which can then be detected by the future operability predictor test. If the current leakage is determined to be above a certain level, the memory cells of the affected bit line can be replaced with redundant memory cells. They can be replaced even though they are presently functional.

Program disturb is another example of a reliability issue that can be identified during reliability testing 248 and for which a future operability predictor test can be developed at step 252. To apply a program voltage to the control gate of a selected cell on a selected NAND string during programming, the program voltage is applied on the appropriate word line. This word line will also be connected to a memory cell on every other NAND string in the selected block of memory cells. Some of these memory cells may not be intended for programming. A problem arises when it's desired to program one cell on a word line without programming other cells connected to the same word line. Because the program voltage is applied to all cells connected to a word line, an unselected cell (a cell that is not to be programmed) connected to the word line may become inadvertently programmed. The unintentional programming of the unselected cell on the selected word line is referred to as “program disturb.” Various techniques including boosting the voltage of the channel regions of NAND strings containing an unselected memory cell are generally used to avoid program disturb.

Some memory cells are weaker and more prone to suffer from program disturb and/or overprogramming (final threshold voltage value higher than intended) than others. During reliability testing, it may be determined that certain memory cells fail to program correctly after repeated write/erase cycling or fail to maintain a stored charge due to their susceptibility to program disturb. It may be discovered that the weaker memory cells manifest their susceptibility to program disturb and/or overprogramming by a high bit line resistance after programming. Accordingly, a future operability test could be developed for the fabrication process that checks for one or more indications of a high bit line resistance indicative of a device that may pose a future operability concern but as of yet, still remains functional. After programming a portion of the memory array, a future operability predictor test may examine the bit line resistance of one or more bit lines. If a bit line has a resistance after programming that is large enough to indicate a future operability concern, even though it is below a threshold level indicative of a failed device, the corresponding column of memory cells can be replaced by redundancy.

In some memory implementations, blocks are implemented as pairs with a column of cells from each block of the pair sharing one ground contact. During functionality testing, a large bit line resistance above a threshold level local to one column may be detected, indicating a failed device. In accordance with one embodiment, a future operability predictor test can identify a column from one paired block that corresponds to a column of the other block in the pair that has actually been determined to be defective. Even though the corresponding column has not been determined to be non-functional, it can be replaced by redundancy since it may pose a future operability concern. Since the column shares a ground contact with the failed column, it is possible that the functional column may fail in the future if the large bit line resistance in the failed column stems from the ground connection. Accordingly, when one column is determined to be defective because of a large bit line resistance, a corresponding functional column from the other block of which the defective column is a part can be identified by future operability predictor testing. The presently functional column can then be replaced by redundancy.

The functionality of a device during erase and soft programming is often checked as part of functionality testing during wafer level and/or package level testing. For example, these tests can identify cells that are not functional because they become over-programmed during soft programming operations. A typical functionality test will examine the memory cells at a selected time (e.g., to) during a soft programming operation to ensure that their threshold voltage stays at or below the soft programming verify level (e.g., −0.8 to −1V). Cells that remain at or below this level are deemed functional while those having threshold voltages above this level are deemed to have been over-programmed from soft programming. These cells are determined to not be functional. It may be discovered during reliability testing that devices passing such erase and soft programming functionality tests fail after or during reliability testing. In accordance with one embodiment, a future operability test is developed and applied to examine the cells and identify those that successfully erase and soft program, but that appear more susceptible to over-soft programming errors. For example, the future operability test can examine the cells at some time after the time period for functionality testing (e.g., t0+X). If a cell's threshold voltage is raised beyond the soft programming verify level at this later time, the cell can be deemed to pose a future operability concern even though it is deemed functional based on the test at time t0. Those cells that indicate a future operability concern from over-soft programming can be replaced by redundant memory cells.

Functionality testing often also includes one or more tests that examine the functionality of a device during read operations. During read or sense operations, the bit line for a memory cell of interest is pre-charged (e.g., to 0.7V) and a reference voltage (e.g., Vra, Vrb, Vrc of FIG. 13) applied to the memory cell. The bit line voltage is then sensed using a sense capacitor after a predetermined amount of time (e.g., t1). If the sense capacitor discharges to a level below an evaluation voltage (e.g., Vsense=0.45V), that memory cell is determined to have been conductive, and thus, have a threshold voltage at or below the applied reference voltage level. The sense capacitor is part of sense block 200. For more information regarding read operations and sensing using sense block 200, see U.S. patent application Ser. No. 11\099,133, entitled “COMPENSATING FOR COUPLING DURING READ OPERATIONS OF NON-VOLATILE MEMORY,” filed Apr. 5, 2005, incorporated by reference in its entirety.

During functionality testing, a memory cell is programmed to a known level. A sense operation is then performed. After the predetermined amount of time that is used during end-user operation of the device, the sense capacitor voltage can be compared with the known threshold voltage of the memory cell. If the sense capacitor voltage does not respond in accordance with the known programmed level of the memory cell, the column of cells can be deemed non-functional. For example, if the known threshold voltage of a memory cell is above the reference voltage level and the capacitor discharges below Vsense before the predetermined amount of time, the column can be deemed defective.

It may be discovered during reliability testing that devices passing read functionality testing fail after or during reliability testing. In accordance with one embodiment, a future operability test is developed and applied to examine and identify those cells or column of cells that read correctly during functionality testing, but that appear more susceptible to future read errors. For example, the future operability test can examine the cells at some time after the predetermined amount of time for sensing (e.g., t1+Y). If the sense capacitor for a column discharges at time t1+Y to below the level to which it should during a normal sense operation at time t1, the column can be deemed to pose a future read operability concern. Accordingly, the column can be replaced by a redundant column of memory cells.

In some testing scenarios, some blocks are selected during package level and/or wafer level testing to undergo write/erase cycling tests. Typically, devices are guaranteed to be operational over some period of write/erase cycling. For example, a device may be guaranteed to operate properly over 10,000 write/erase cycles. During testing, the selected blocks can undergo a number of write/erase cycles to test the devices reliability. A test process may perform 4,000 write/erase cycles, and then use the results of that testing to predict what will happen after the block undergoes 10,000 write/erase cycles. If a block is not predicted to be able to withstand 10,000 write/erase cycles, the entire device of which the block is a part is deemed non-functional and failed. If each selected block for a device passes the write/erase cycling test, the device is deemed functional. In accordance with one embodiment, blocks that undergo the write/erase cycling test and pass (functional blocks) are replaced using redundant blocks. The operational life of these selected blocks may be less than that of other blocks in the device since they have undergone 4,000 write/erase cycles prior to use by an end-user. Accordingly, these selected blocks may pose a future operability concern and can be replaced using any available redundancy to improve reliability.

The future operability tests developed as a result of reliability testing can include both the tests performed to detect future operability concerns, as well as the stress conditions designed to cause an indication or manifestation of the concern which then can be detected by one of the actual tests. For example, a stress condition to induce current leakage in a bit line could be developed along with a test to determine if the current leakage for any bit lines is above a predetermined level.

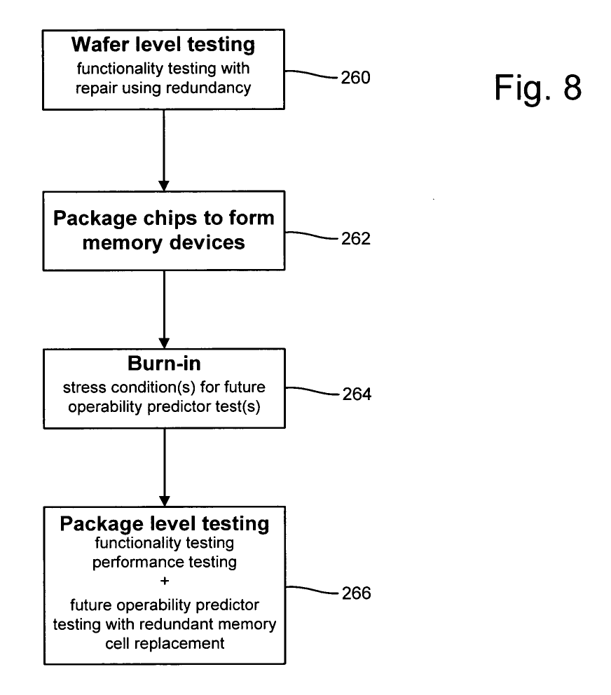

The future operability tests and associated stress conditions can be inserted into the main fabrication process at various points at step 254. FIG. 8 depicts one embodiment where future operability testing with redundant memory cell replacement is used during package level testing. The method of FIG. 8 can be performed for a production line fabrication process after performing reliability testing on selected memory devices that have already undergone fabrication. Thus, FIG. 8 represents a modification of an initial fabrication process, such as depicted in steps 240-246 of FIG. 7.

At step 260, one or more wafers of memory chips undergo wafer level testing. Wafer level testing 260 includes functionality testing and replacement of those memory cells determined to be defective. Wafer level testing can also include the application of various stress conditions to the wafers prior to testing. After testing the wafers and replacing defective cells with redundant ones, the wafers are divided into individual chips which are packaged to form semiconductor memory devices (e.g., plastic memory card) at step 262.

At step 264, the packaged devices are subjected to an optional burn-in as previously described. In FIG. 8, however, the burn-in process has been modified to include the application of one or more future operability predictor burn-in conditions. The additional burn-in conditions are designed to cause a detectable indication for memory cells that pose a future operability concern. For example, the additional burn-in stress conditions could include high voltages applied to bit lines or other parts of the circuits. In one embodiment, burn-in 264 is performed at the wafer level prior to packaging the devices at step 262. In some embodiments, future operability stress conditions can be provided during wafer level testing in addition to or in place of a separate burn-in operation 264. At step 266, package level testing is performed for each packaged memory device. As with conventional package level testing, functionality testing and performance testing can be performed. Redundant memory cells can be used to replace those memory cells that fail functionality testing. In addition to functionality and performance testing, however, the method of FIG. 8 includes the performance of one or more future operability predictor tests. Future operability predictor tests are used to identify functional memory cells that may pose a future operability concern. These are cells that pass the functionality tests, but that in some way exhibit an indication that their future operability is suspect. In one embodiment, stress conditions including those designed to identify future operability predictor concerns can be implemented during package level testing 266 in addition to or in place of applying these stress conditions during burn-in 264.

Memory cells that fail one or more future operability tests are replaced with redundant memory cells of the memory array. In one embodiment, the memory cells that fail future operability predictor testing are only replaced if redundant memory cells remain after functionality testing during wafer level and/or package level testing. In this manner, priority is given to the replacement of defective or non-functional memory cells.

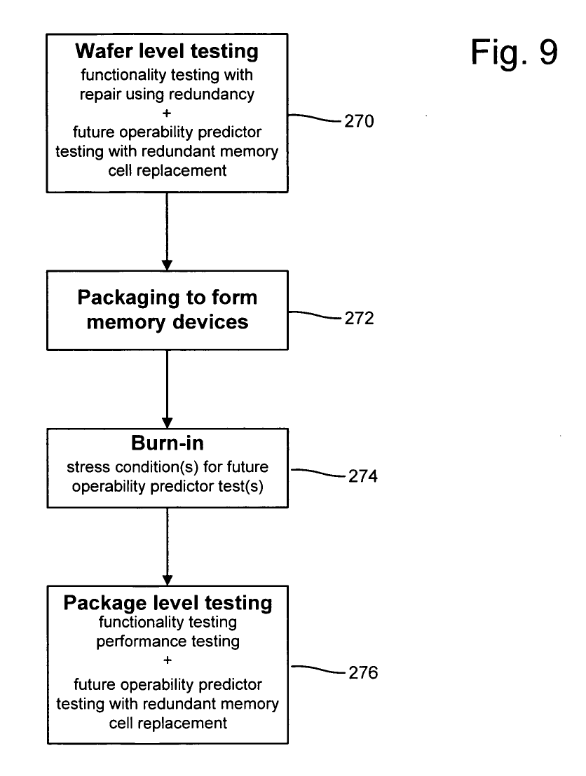

FIG. 9 depicts an embodiment where future operability predictor testing has been incorporated into wafer level testing. During wafer level testing at step 270, one or more future operability predictor tests are applied. Additionally, various associated stress conditions can be applied. The stress conditions can cause a detectable indication that certain memory cells may pose a future operability concern. Memory cells that fail one or more future operability predictor tests can be replaced with redundant memory cells of the memory array. Again, priority can be given to the replacement of defective cells by only replacing cells that pose a future operability concern if redundant memory cells remain after functionality testing.

The wafers are divided into individual memory chips which are packaged at step 272 to form the memory devices. The devices are subjected to an optional burn-in at step 274 and package level testing at step 276. In FIG. 9, burn-in 274 and package level testing 276 include further future operability predictor testing. Any redundant memory cells remaining after wafer level testing and package level functionality testing can be used to replace memory cells that may pose a future operability concern. In one embodiment, future operability predictor testing is not performed during package level testing. In one embodiment, burn-in 274 is performed prior to packaging at step 272 and the burn-in process can include the application of stress conditions at the wafer level to identify cells that pose a future operability concern.

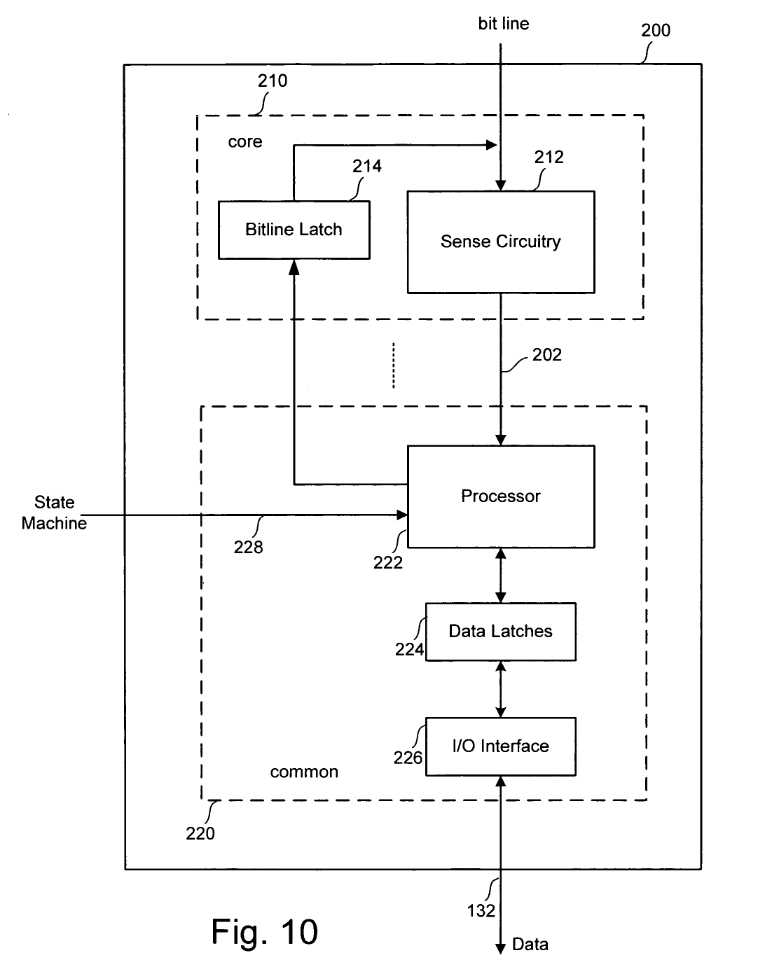

Further details regarding one semiconductor memory device that can be fabricated in accordance with embodiments are depicted in FIGS. 10-15. FIG. 10 is a block diagram of an individual sense block 200 partitioned into a core portion, referred to as a sense module 210, and a common portion 220. In one embodiment, there will be a separate sense module 210 for each bit line and one common portion 220 for a set of multiple sense modules 210. In one example, a sense block will include one common portion 220 and eight sense modules 210. Each of the sense modules in a group will communicate with the associated common portion via a data bus 202. For further details, refer to U.S. patent application Ser. No. 11/026,536, entitled “Non-Volatile Memory & Method with Shared Processing for an Aggregate of Sense Amplifiers,” filed on Dec. 29, 2004 and incorporated by reference herein in its entirety.

Sense module 210 comprises sense circuitry 212 that determines whether a conduction current in a connected bit line is above or below a predetermined threshold level. Sense module 210 also includes a bit line latch 214 that is used to set a voltage condition on the connected bit line. For example, a predetermined state latched in bit line latch 214 will result in the connected bit line being pulled to a state designating program inhibit (e.g., Vdd).

Common portion 220 comprises a processor 222, a set of data latches 224 and an I/O Interface 226 coupled between the set of data latches 224 and data bus 132. Processor 222 performs computations. For example, one of its functions is to determine the data stored in the sensed memory cell and store the determined data in the set of data latches. Processor 222 can also perform certain functions dependent upon instructions from the state machine and/or data in latches 224, for example, setting appropriate conditions in bit line latch 214 based on the type of operation being performed. The set of data latches 224 is used to store data bits determined by processor 222 during a read operation. It is also used to store data bits imported from the data bus 132 during a program operation. The imported data bits represent write data meant to be programmed into the memory. I/O interface 226 provides an interface between data latches 224 and the data bus 132.

During read or sensing, the operation of the system is under the control of state machine 122 that controls the supply of different control gate voltages to the addressed cell. As it steps through the various predefined control gate voltages corresponding to the various memory states supported by the memory, the sense module 210 will trip at one of these voltages and an output will be provided from sense module 210 to processor 222 via bus 202. At that point, processor 222 determines the resultant memory state by consideration of the tripping event(s) of the sense module and the information about the applied control gate voltage from the state machine via input lines 228. It then computes a binary encoding for the memory state and stores the resultant data bits into data latches 224. In another embodiment of the core portion, bit line latch 214 serves double duty, both as a latch for latching the output of the sense module 210 and also as a bit line latch as described above.

It is anticipated that some implementations will include multiple processors 222. In one embodiment, each processor 222 will include an output line (not depicted in FIG. 7) such that each of the output lines is wired-OR'd together. In some embodiments, the output lines are inverted prior to being connected to the wired-OR line. This configuration enables a quick determination during the program verification process of when the programming process has completed because the state machine receiving the wired-OR can determine when all bits being programmed have reached the desired level. For example, when each bit has reached its desired level, a logic zero for that bit will be sent to the wired-OR line (or a data one inverted). When all bits output a data 0 (or a data one inverted), then the state machine knows to terminate the programming process. Because each processor communicates with eight sense modules, the state machine needs to read the wired-OR line eight times.

During program or verify, the data to be programmed is stored in the set of data latches 224 from the data bus 132. The program operation, under the control of the state machine, comprises a series of programming voltage pulses applied to the control gates of the addressed memory cells. Each programming pulse is followed by a read back (verify) to determine if the cell has been programmed to the desired memory state. Processor 222 monitors the read back memory state relative to the desired memory state. When the two are in agreement, the processor 222 sets the bit line latch 214 so as to cause the bit line to be pulled to a state designating program inhibit. This inhibits the cell coupled to the bit line from further programming even if programming pulses appear on its control gate. In other embodiments the processor initially loads the bit line latch 214 and the sense circuitry sets it to an inhibit value during the verify process.

Data latch stack 224 contains a stack of data latches corresponding to the sense module. In one embodiment, there are three data latches per sense module 210. For example, there can be a lower data latch for storing data for a lower page read or write, an upper data latch for storing data for an upper page read or write, and one additional latch. Additional or fewer data latches can be used according to specific implementations in accordance with embodiments. In some implementations (but not required), the data latches are implemented as a shift register so that the parallel data stored therein is converted to serial data for data bus 132, and vice versa. In one embodiment, all the data latches corresponding to the read/write block of n memory cells can be linked together to form a block shift register so that a block of data can be input or output by serial transfer. In particular, the bank of read/write modules is adapted so that each of its set of data latches will shift data in to or out of the data bus in sequence as if they are part of a shift register for the entire read/write block.

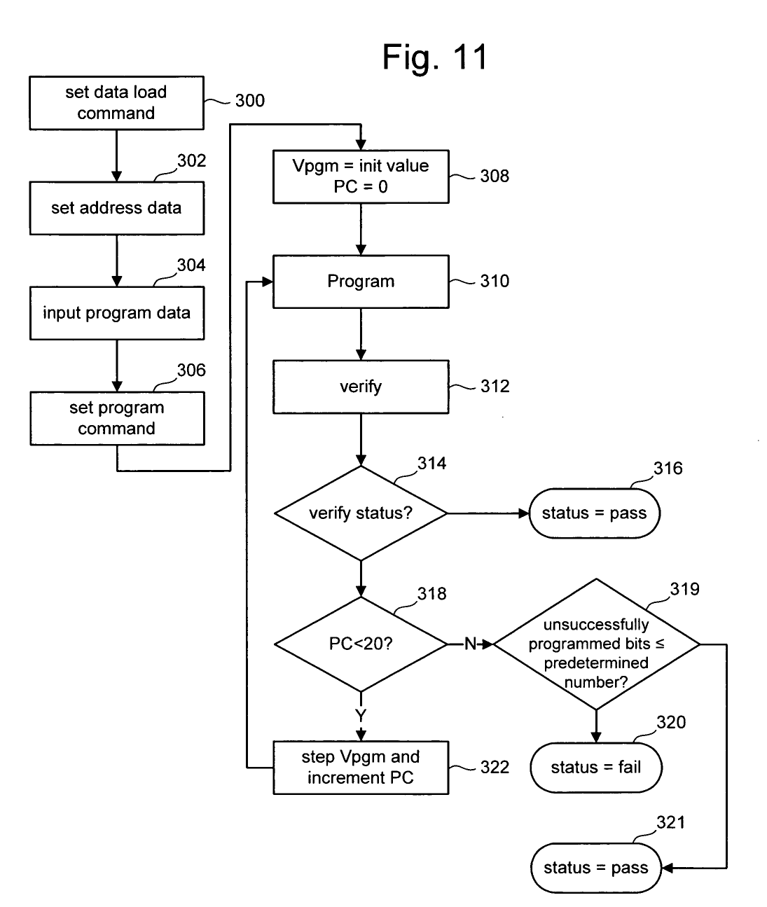

FIG. 11 is a flow chart describing one embodiment of a method for programming non-volatile memory. In one implementation, memory cells are erased (in blocks or other units) prior to programming. In step 300 of FIG. 11, a “data load” command is issued by the controller and input received by control circuitry 120. In step 302, address data designating the page address is input to decoder 124 from the controller or host. In step 304, a page of program data for the addressed page is input to a data buffer for programming. That data is latched in the appropriate set of data latches 224. In step 306, a “program” command is issued by the controller to state machine 122.

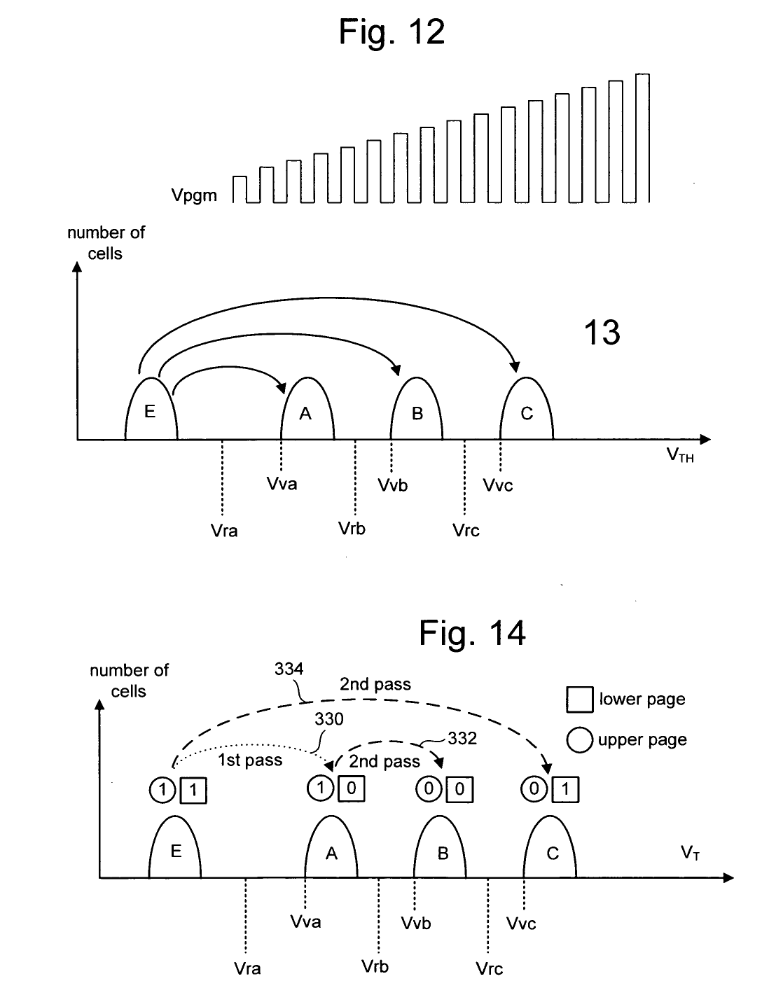

Triggered by the “program” command, the data latched in step 304 will be programmed into the selected memory cells controlled by state machine 122 using the stepped pulses of FIG. 12 applied to the appropriate word line. In step 308, Vpgm, the programming pulse voltage level applied to the selected word line, is initialized to the starting pulse (e.g., 12V) and a program counter PC maintained by state machine 122 is initialized at 0. In step 310, the first Vpgm pulse is applied to the selected word line. If logic “0” is stored in a particular data latch indicating that the corresponding memory cell should be programmed, then the corresponding bit line is grounded. On the other hand, if logic “1” is stored in the particular latch indicating that the corresponding memory cell should remain in its current data state, then the corresponding bit line is connected to Vdd to inhibit programming.

In step 312, the states of the selected memory cells are verified. If it is detected that the target threshold voltage of a selected cell has reached the appropriate level, then the data stored in the corresponding data latch is changed to a logic “1.” If it is detected that the threshold voltage has not reached the appropriate level, the data stored in the corresponding data latch is not changed. In this manner, a bit line having a logic “1” stored in its corresponding data latch does not need to be programmed. When all of the data latches are storing logic “1,” the state machine (via the wired-OR type mechanism described above) knows that all selected cells have been programmed. In step 314, it is checked whether all of the data latches are storing logic “1.” If so, the programming process is complete and successful because all selected memory cells were programmed and verified to their target states. A status of “PASS” is reported in step 316.

If, in step 314, it is determined that not all of the data latches are storing logic “1,” then the programming process continues. In step 318, the program counter PC is checked against a program limit value. One example of a program limit value is 20, however, other values can be used in various implementations. If the program counter PC is not less than 20, then it is determined at step 319 whether the number of bits that have not been successfully programmed is equal to or less than a predetermined number. If the number of unsuccessfully programmed bits is equal to or less than the predetermined number, then the programming process is flagged as passed and a status of pass is reported at step 321. The bits that are not successfully programmed can be corrected using error correction during the read process. If however, the number of unsuccessfully programmed bits is greater than the predetermined number, the program process is flagged as failed and a status of fail is reported at step 320. If the program counter PC is less than 20, then the Vpgm level is increased by the step size and the program counter PC is incremented in step 322. After step 322, the process loops back to step 310 to apply the next Vpgm pulse.

At the end of a successful program process, the threshold voltages of the memory cells should be within one or more distributions of threshold voltages for programmed memory cells or within a distribution of threshold voltages for erased memory cells, as appropriate. FIG. 13 illustrates threshold voltage distributions for the memory cell array when each memory cell stores two bits of data. FIG. 13 shows a first threshold voltage distribution E for erased memory cells. Three threshold voltage distributions, A, B and C for programmed memory cells, are also depicted. In one embodiment, the threshold voltages in the E distribution are negative and the threshold voltages in the A, B and C distributions are positive.

Each distinct threshold voltage range of FIG. 13 corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a floating gate erroneously shifts to its neighboring physical state, only one bit will be affected. One example assigns “11” to threshold voltage range E (state E), “10” to threshold voltage range A (state A), “00” to threshold voltage range B (state B) and “01” to threshold voltage range C (state C). However, in other embodiments, Gray code is not used. Although FIG. 11 shows four states, the present invention can also be used with other multi-state structures including those that include more or less than four states.

FIG. 13 also shows three read reference voltages, Vra, Vrb and Vrc, for reading data from memory cells. By testing whether the threshold voltage of a given memory cell is above or below Vra, Vrb and Vrc, the system can determine what state the memory cell is in. FIG. 13 also shows three verify reference voltages, Vva, Vvb and Vvc. When programming memory cells to state A, the system will test whether those memory cells have a threshold voltage greater than or equal to Vva. When programming memory cells to state B, the system will test whether the memory cells have threshold voltages greater than or equal to Vvb. When programming memory cells to state C, the system will determine whether memory cells have their threshold voltage greater than or equal to Vvc.

In one embodiment as depicted in FIG. 13, known as full sequence programming, memory cells can be programmed from the erase state E directly to any of the programmed states A, B or C. For example, a population of memory cells to be programmed may first be erased so that all memory cells in the population are in erased state E. The process depicted in FIG. 13, using the control gate voltage sequence depicted in FIG. 12, will then be used to program memory cells directly into states A, B or C. While some memory cells are being programmed from state E to state A, other memory cells are being programmed from state E to state B and/or from state E to state C. In such embodiments, both bits coded for a particular memory state of a memory cell can be regarded as part of a single page of data.

FIG. 14 illustrates an example of a two-pass technique of programming a multi-state memory cell that stores data for two different pages: a lower page and an upper page. Four states are depicted: state E (11), state A (10), state B (00) and state C (01). For state E, both pages store a “1.” For state A, the lower page stores a “0” and the upper page stores a “1.” For state B, both pages store “0.” For state C, the lower page stores “1” and the upper page stores “0.” Note that although specific bit patterns have been assigned to each of the states, different bit patterns may also be assigned. In a first programming pass, the cell's threshold voltage level is set according to the bit to be programmed into the lower logical page. If that bit is a logic “1,” the threshold voltage is not changed since it is in the appropriate state as a result of having been earlier erased. However, if the bit to be programmed is a logic “0,” the threshold level of the cell is increased to be state A, as shown by arrow 330. That concludes the first programming pass.

In a second programming pass, the cell's threshold voltage level is set according to the bit being programmed into the upper logical page. If the upper logical page bit is to store a logic “1,” then no programming occurs since the cell is in one of the states E or A, depending upon the programming of the lower page bit, both of which carry an upper page bit of “1.” If the upper page bit is to be a logic “0,” then the threshold voltage is shifted. If the first pass resulted in the cell remaining in the erased state E, then in the second phase the cell is programmed so that the threshold voltage is increased to be within state C, as depicted by arrow 334. If the cell had been programmed into state A as a result of the first programming pass, then the memory cell is further programmed in the second pass so that the threshold voltage is increased to be within state B, as depicted by arrow 332. The result of the second pass is to program the cell into the state designated to store a logic “0” for the upper page without changing the data for the lower page.

In one embodiment, a system can be set up to perform full sequence writing if enough data is written to fill up an entire page. If not enough data is written for a full page, then the programming process can program the lower page programming with the data received. When subsequent data is received, the system will then program the upper page. In yet another embodiment, the system can start writing in the mode that programs the lower page and convert to full sequence programming mode if enough data is subsequently received to fill up an entire (or most of a) word line's memory cells. More details of such an embodiment are disclosed in U.S. patent application titled “Pipelined Programming of Non-Volatile Memories Using Early Data,” Ser. No. 11/013,125, filed on Dec. 14, 2004, inventors Sergy Anatolievich Gorobets and Yan Li, incorporated herein by reference in its entirety.

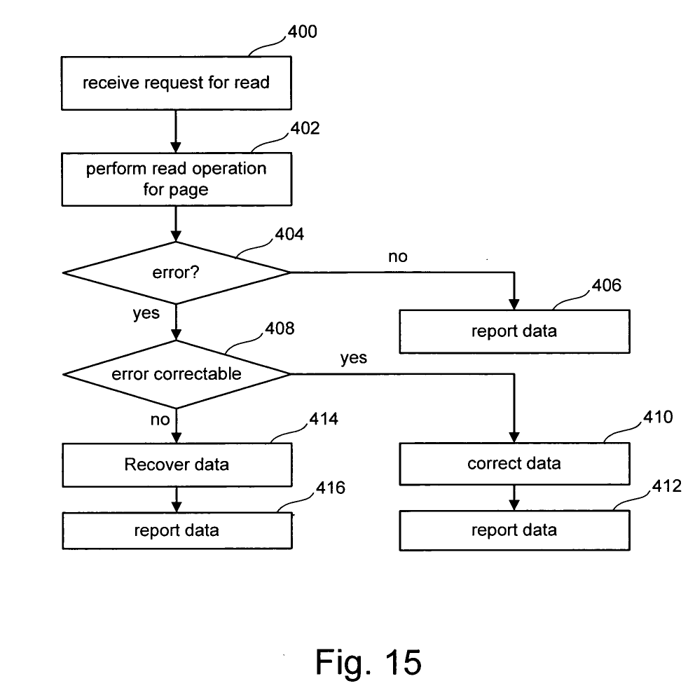

FIG. 15 is a flow chart describing one embodiment for reading data from non-volatile memory cells. FIG. 15 provides the read process at the system level. At step 404, a read operation is performed for a particular page in response to a request to read data received at step 402. In one embodiment, when data for a page is programmed, the system will also create Error Correction Codes (ECCs) and write those ECCs with the page of data. ECC technologies are well known in the art. The ECC process used can include any suitable ECC process known in the art. When reading data from a page, the ECCs will be used to determine whether there are any errors in the data (step 404). The ECC process can be performed on he controller, the state machine or elsewhere in the system. If there are no errors in the data, the data is reported to the user at step 406. For example, data will be communicated to a controller or host via data I/O lines 134. If an error is found at step 404, it is determined whether the error is correctable at step 408. The error may be due to the floating gate to floating gate coupling effect or possibly to other physical mechanisms. Various ECC methods have the ability to correct a predetermined number of errors in a set of data. If the ECC process can correct the data, then the ECC process is used to correct that data at step 410 and the data, as corrected, is reported to the user in step 412. If the data is not correctable by the ECC process, a data recovery process is performed in step 414. In some embodiments, an ECC process will be performed after step 414. After the data is recovered, that data is reported at step 416. Note that the process of FIG. 15 can be used with data programmed using all bit line programming or odd/even bit line programming.

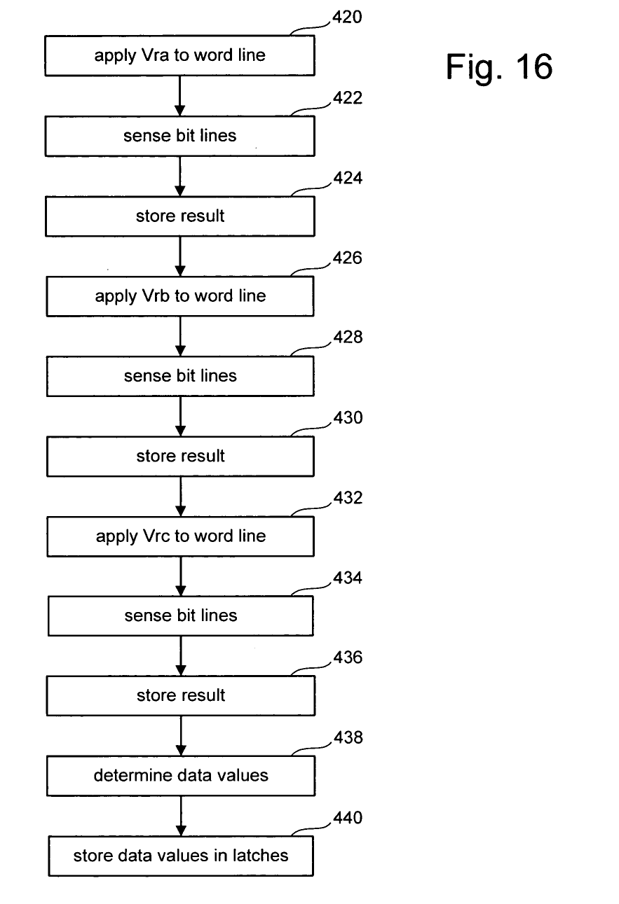

FIG. 16 is a flow chart describing one embodiment of a process for performing a read operation for a page. The process of FIG. 16 can be performed for a page that encompasses all bit lines of a block, only odd bit lines of a block, only even bit lines of a block, or other subsets of bit lines of a block. In step 420, read reference voltage Vra is applied to the appropriate word line associated with the page. In step 422, the bit lines associated with the page are sensed to determine whether the addressed memory cells conduct or do not conduct based on the application of Vra to their control gates. Bit lines that conduct indicate that the memory cells were turned on; therefore, the threshold voltages of those memory cells are below Vra (e.g., in state E). In step 424 the result of the sensing for the bit lines is stored in the appropriate latches for those bit lines. In step 426, read reference voltage Vrb is applied to the word lines associated with the page being read. In step 428, the bit lines are sensed as described above. In step 430, the results are stored in the appropriate latches for the bit lines. In step 432, read reference voltage Vrc is applied to the word lines associated with the page. In step 434, the bit lines are sensed to determine which memory cells conduct, as described above. In step 436, the results from the sensing step are stored in the appropriate latches for the bit lines. In step 838, the data values for each bit line are determined. For example, if a memory cell conducts at Vra, then the memory cell is in state E. If a memory cell conducts at Vrb and Vrc but not at Vra, then the memory cell is in state A. If the memory cell conducts at Vrc but not at Vra and Vrb, then the memory cell is in state B. If the memory cell does not conduct at Vra, Vrb or Vrc, then the memory cell is in state C. In one embodiment, the data values are determined by processor 222. In step 440, processor 222 will store the determined data values in the appropriate latches for each bit line. In other embodiments, sensing the various levels (Vra, Vrb, and Vrc) may occur in different orders.

Different numbers of reference read voltages may need to be applied in various embodiments based on the coding and/or architecture employed. For example, when an upper page/lower page architecture is employed and a coding scheme as illustrated in FIG. 14 used, an upper page read may be accomplished simply by using the Vrb read reference voltage level to determine whether a memory cell is in one of states E and A (upper page bit=1) or in one of states B and C (upper page bit=0). A lower page read may be accomplished by using the Vra and Vrc read reference voltage levels to determine whether a memory cell is in one of states E and C (lower page bit=1) or one of states A and B (lower page bit=0).

Although NAND type flash memory has been principally described for exemplary purposes, the present disclosure is not so limited and has application to numerous types of integrated circuits that rely on redundant elements. In principle, embodiments can be used in any type of circuit employing redundancy. Other embodiments may include NOR type flash memory and volatile memories such as SRAM and DRAM.

The foregoing detailed description of the invention has been presented for purposes of illustration and description. It is not intended to be exhaustive or to limit the invention to the precise form disclosed. Many modifications and variations are possible in light of the above teachings. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

I claim:

1. A method of manufacturing integrated circuits, comprising:
testing a plurality of circuit devices by applying at least one functionality test and at least one future operability test, said circuit devices include a plurality of primary storage elements and a plurality of redundant storage elements; and
replacing primary storage elements that pass said at least one functionality test but fail said at least one future operability test with redundant storage elements of said circuit devices.

2. The method of claim 1, wherein:
said testing is wafer level testing; and
said circuit devices are memory chips on a wafer, each memory chip including at least one memory array.

3. The method of claim 1, wherein:
said testing is package level testing; and
said circuit devices are packaged memory devices, wherein each packaged memory device includes at least one chip having at least one memory array.

4. The method of claim 3, wherein each of said packaged memory devices further includes a controller in communication with said at least one chip.

5. The method of claim 1, wherein said plurality of circuit devices is a first plurality of circuit devices, said method further comprising:
testing a second plurality of circuit devices by applying at least one reliability test;
identifying a storage element failure resulting from said at least one reliability test;
formulating said at least one future operability test based on said at least one reliability test and said storage element failure, said formulating includes designing said at least one future operability test to identify functional storage elements that may experience said storage element failure prior to said storage element failure occurring in said functional storage elements.

6. The method of claim 5, wherein:
said at least one future operability test includes a test and a stress condition; and
formulating said at least one future operability test includes formulating said test and said stress condition based on said at least one reliability test and said storage element failure.

7. The method of claim 5, wherein:
said circuit devices of said first plurality each include a plurality of bit lines;
said memory element failure is a shorted bit line;
said at least one future operability test determines whether any of said bit lines has a leakage current above a predetermined level;
replacing primary storage elements that fail said at least one future operability test includes replacing at least one primary storage element associated with a bit line having a leakage current above said predetermined level.

8. The method of claim 1, wherein:
testing by applying said at least one future operability predictor test includes identifying functional but weaker storage elements with greater susceptibility to program disturb than other storage elements of said plurality of circuit devices.

9. The method of claim 1, wherein:
said plurality of primary storage elements and said plurality of redundant storage elements are organized into a plurality of NAND strings.

10. The method of claim 1, wherein:
said plurality of primary storage elements and said plurality of redundant storage elements are multi-state flash memory cells.

11. A method of manufacturing integrated circuits, comprising:
testing a plurality of circuit devices by applying at least one functionality test and at least one future operability test, said circuit devices include a plurality of primary storage elements and a plurality of redundant storage elements; and
replacing primary storage elements that fail said at least one future operability test with redundant storage elements of said circuit devices.

12. The method of claim 11, wherein replacing primary storage elements that fail said at least one future operability test comprises:
replacing primary storage elements that fail said at least one future operability test but pass said at least one functionality test with redundant storage elements of said circuit devices.

13. The method of claim 11, wherein:
said testing is wafer level testing; and
said circuit devices are memory chips on a wafer, each memory chip including at least one memory array.

14. The method of claim 11, wherein:
said testing is package level testing; and
said circuit devices are packaged memory devices, wherein each packaged memory device includes at least one chip having at least one memory array.

15. The method of claim 11, wherein said plurality of circuit devices is a first plurality of circuit devices, said method further comprising:
testing a second plurality of circuit devices by applying at least one reliability test;
identifying a storage element failure resulting from said at least one reliability test;
formulating said at least one future operability test based on said at least one reliability test and said storage element failure, said formulating includes designing said at least one future operability test to identify functional storage elements that may experience said storage element failure prior to said storage element failure occurring in said functional storage elements.

16. The method of claim 11, wherein:
said plurality of primary storage elements and said plurality of redundant storage elements are organized into a plurality of NAND strings.

17. A method of manufacturing integrated circuits, comprising:
applying a reliability test to a first plurality of packaged circuit devices;
detecting a failure associated with a portion of one or more packaged circuit devices of said first plurality after applying said reliability test;
formulating a future operability predictor test in response to said applying and detecting, said future operability predictor test is formulated to detect a potential for said failure in a second plurality of circuit devices, each circuit device of said second plurality includes primary storage elements and redundant storage elements;
applying said future operability predictor test to said second plurality of circuit devices; and
replacing selected primary storage elements of said second plurality of circuit devices with redundant storage elements of said second plurality of circuit devices based on a result of said future operability predictor test.

18. The method of claim 17, wherein:
said second plurality of circuit devices is a second plurality of packaged circuit devices; and
said future operability predictor test is applied during package level testing of said second plurality of packaged devices.

19. The method of claim 17, wherein:
said second plurality of circuit devices is a second plurality of pre-packaging memory chips that each include at least one memory array;
said future operability predictor test is applied during wafer level testing of said second plurality of pre-packaging memory chips.

20. The method of claim 17, wherein:
replacing primary storage elements includes replacing at least one primary storage element that is determined to be functional with a redundant storage element.

21. The method of claim 17, wherein:
said primary storage elements and said redundant storage elements are binary flash memory cells.

22. A method of manufacturing integrated circuits, comprising:
testing at least one wafer including a plurality of memory chips, each of said memory chips including primary storage elements and redundant storage elements, said testing includes replacing primary storage elements that fail functionality testing with redundant storage elements;
creating a packaged memory device from one or more of said memory chips;
stressing said packaged memory device;
testing said packaged memory device by applying at least one functionality test and at least one future operability predictor test; and
replacing primary storage elements of said packaged memory device that pass said at least one functionality test but fail said at least one future operability predictor test with redundant storage elements of said packaged memory device.

23. The method of claim 22, wherein:
stressing said packaged memory device includes applying at least one condition to said packaged memory device that is designed to cause an indication for ones of said primary storage elements that pose a future operability concern;
applying said at least one future operability predictor test includes detecting said indication in said ones of said primary storage elements that pose a future operability concern.

24. The method of claim 22, wherein testing said at least one wafer includes:
applying at least one functionality test and at least one future operability predictor test; and
replacing primary storage elements of said at least one wafer that pass said at least one functionality test but fail said at least one future operability test with redundant storage elements.

25. The method of claim 22, wherein:
said primary storage elements are multi-state flash memory cells.

26. A method of manufacturing integrated circuits, comprising:
testing whether at least a portion of a circuit device is functional, said circuit device including primary storage elements and redundant storage elements;
replacing primary storage elements that are determined not to be functional with redundant storage elements;
testing whether primary storage elements of said circuit device that are determined to be functional may pose a future operability concern; and
replacing with redundant storage elements those primary storage elements of said circuit device that are determined to be functional but pose a future operability concern.

27. The method of claim 26, wherein:
said circuit device is a memory chip on a wafer; and
testing whether at least a portion of said circuit device is functional and testing whether primary memory elements of said circuit device that are determined to be functional may pose a future operability concern are both performed during wafer level testing of said wafer.

28. The method of claim 26, wherein:
said circuit device is a packaged memory device including at least one memory chip; and
testing whether at least a portion of said circuit device is functional and testing whether primary memory elements of said circuit device that are determined to be functional may pose a future operability concern are both performed during package level testing for said packaged memory device.

29. The method of claim 26, wherein testing whether primary storage elements of said circuit device that are determined to be functional may pose a future operability concern includes:
applying at least one condition to said circuit device designed to cause an indication for ones of said functional primary storage elements that may pose a future operability concern; and
determining whether said indication is present for said functional primary storage elements.

30. The method of claim 26, wherein said circuit device is a first circuit device, said method further comprising:
testing a second circuit device by applying at least one reliability test;
identifying a failure associated with said second circuit device resulting from said at least one reliability test; and
formulating said at least one future operability test based on said at least one reliability test and said failure associated with said second circuit device, said formulating includes designing said at least one future operability test to identify functional storage elements that may experience said failure prior to said failure occurring.

31. The method of claim 30, wherein:
said at least one future operability test includes a test and a stress condition; and
formulating said at least one future operability test includes formulating said test and said stress condition based on said at least one reliability test and said failure associated with said second circuit device.

32. The method of claim 26, wherein:
said primary storage elements are organized into a plurality of NAND strings.
